(19) United States
(12) Patent Application Publication
(10) Pub. No.: US 2024/0399534 A1
(43) Pub. Date: Dec. 5, 2024

(54) PROCESSING MACHINE AND METHOD FOR MANUFACTURING OBJECT TO BE PROCESSED

(71) Applicant: SHIBAURA MACHINE CO., LTD., Tokyo (JP)

(72) Inventor: Takanobu AKIYAMA, Shizuoka-ken (JP)

(73) Assignee: SHIBAURA MACHINE CO., LTD., Tokyo (JP)

(21) Appl. No.: 18/698,510

(22) PCT Filed: Sep. 6, 2022
(86) PCT No.: PCT/JP22/33377

§ 371 Date: Apr. 4, 2024

(30) Foreign Application Priority Data
Oct. 12, 2021 (JP) 2021-167156

(51) Int. Cl. B24B 47/22; B24B 41/04; B24B 55/02

(52) U.S. Cl. CPC B24B 47/22; B24B 41/04; B24B 55/02

(57) ABSTRACT

In a processing machine, a drive part makes a movable part move in a first direction. A position sensor detects the position of the movable part in the first direction. The rotation sensor detects the rotation of the spindle. At the time of processing of a workpiece by a tool in a state where the spindle is rotating, a control part controls the drive part based on the detection value of the position sensor so as to the movable part move in the first direction to a relative position set with respect to a predetermined reference position. Further, the control part acquires, as the reference position, a position detected by the position sensor at the time of detection of cessation of rotation of the spindle by the rotation sensor in a situation where the movable part moves in the first direction in a state where the spindle is rotating, and the tool and the workpiece contact in the first direction.

### TECHNICAL FIELD

The present disclosure relates to a processing machine and a method for manufacturing a processed object.

### BACKGROUND ART

Known in the art is a processing machine which performs processing (for example cutting) on a workpiece by a tool (for example the following PTL 1 and PTL 2). PTL 1 and PTL 2 disclose a cutting apparatus (processing machine) which uses a blade (tool) having a cutting edge on its outer periphery to divide a wafer (workpiece). Such a processing machine, for example, makes the blade to a relative position set with respect to a predetermined reference position to realize a desired depth of cut and the like.

The information of position serving as the reference position is for example acquired by making the blade approach the workpiece or a table holding the workpiece and detecting the position of the blade at the time when contact of the two is detected. In the section of Background Art of PTL 1 and PTL 2, the art of using a blade and table which are conductive, and utilizing the current conducted at the time of contact of the two to detect the contact of the two is disclosed.

When the blade and the table contact, there is a possibility of an issue arising such as deterioration of either one of the two. Therefore, PTL 1 proposes the art of applying a high frequency voltage to the blade and the table and detecting approach of the two based on the change of electrostatic capacitance between the two. PTL 2 proposes the art of acquiring information of the position serving as the reference position by using a pseudo blade simulating a blade in place of the blade.

### CITATION LIST

### Patent Literature

PTL 1: Japanese Patent Publication No. 61-071967
PTL 2: Japanese Patent Publication No. 2015-103693

### SUMMARY OF INVENTION

### Technical Problem

In the art of PTL 1, use must be made of a blade which is conductive. That is, the degree of freedom of selection of the blade falls. In the art of PTL 2, a pseudo blade becomes necessary in addition to the blade. Further, error may occur caused by the difference between the blade and the pseudo blade. Accordingly, a processing machine and manufacturing method of the processed object able to suitably acquire information of the position serving as the reference position are being awaited.

### Solution to Problem

A processing machine according to one aspect of the present disclosure includes a spindle, holding part, drive part, position sensor, rotation sensor, and control part. The spindle holds one of a tool and a workpiece. The holding part holds the other of the tool and the workpiece. The drive part moves one of the spindle and the holding part as a movable part in a predetermined first direction. The position sensor detects the position of the movable part in the first direction. The rotation sensor detects rotation of the spindle. When the workpiece is processed by the tool in a state where the spindle is rotating, the control part controls the drive part based on the detection value of the position sensor so as to move the movable part in the first direction to a relative position which is set with respect to the predetermined reference position. The workpiece or member which is does not move relative to the workpiece will be referred to as a “reference member”. The control part acquires as the reference position the position detected by the position sensor when a cessation of rotation of the spindle is detected by the rotation sensor in a situation where the movable part moves in the first direction in a state where the spindle is rotating and the tool and the reference member contact in the first direction.

A manufacturing method of a processed object according to one aspect of the present disclosure uses the processing machine to process the workpiece by the tool to obtain the processed object.

### Advantageous Effect of Invention

According to the above configuration or procedure, information of a reference position when making a workpiece and a tool relatively move can be suitably acquired.

### BRIEF DESCRIPTION OF DRAWINGS

FIG. 1 is a schematic perspective view showing a principal part of a processing machine according to an embodiment of the present disclosure.

FIG. 2 is a schematic perspective view showing a part of the processing machine in FIG. 1 enlarged.

FIG. 3 is a cross-sectional view schematically showing a bearing of a spindle in the processing machine in FIG. 1.

FIG. 4 is a block diagram schematically showing the configuration of a signal processing system in the processing machine in FIG. 1.

FIG. 5A and FIG. 5B are schematic views for explaining an operation relating to acquisition of information of a reference position by the processing machine in FIG. 1.

FIG. 6 is a flow chart showing an example of the procedure for acquiring information of a reference position in the processing machine in FIG. 1.

### EMBODIMENTS OF INVENTION

First, an outline of a processing machine according to one embodiment of the present disclosure will be explained, then details of the processing machine will be explained.

### (Outline of Processing Machine)

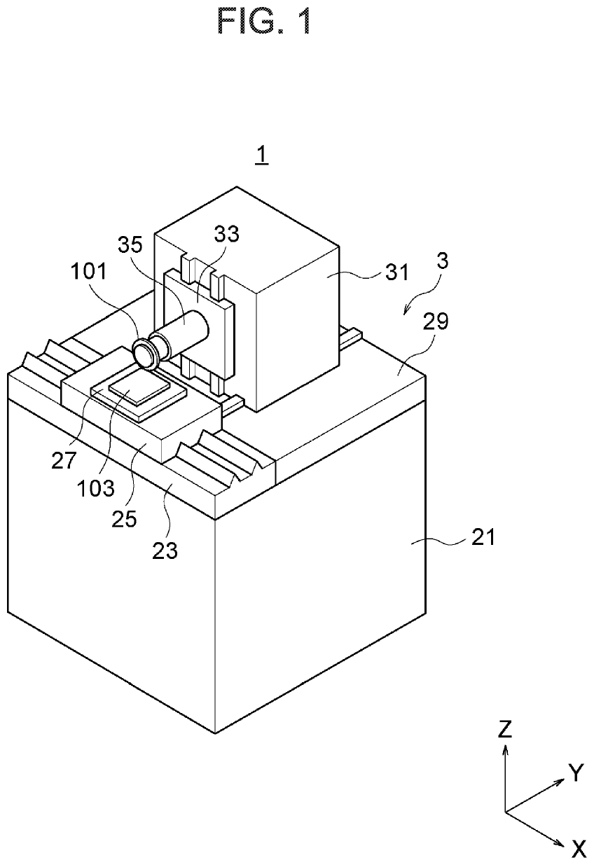

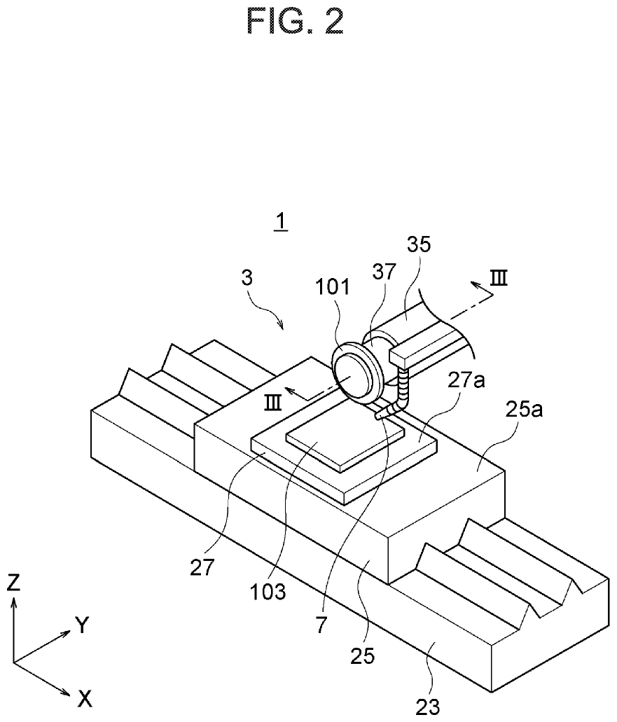

FIG. 1 is a schematic perspective view showing the principal part of a processing machine 1 according to an embodiment of the present disclosure. FIG. 2 is a schematic perspective view showing a part of the processing machine 1 in FIG. 1 enlarged.

The relationships between the orientations of the various members shown and the vertical direction may be any relationships. However, the following explanation, for convenience, will be sometimes given predicated on the relationships between orientations of various members and the vertical direction as illustrated in the figures. To the figures, for convenience, an orthogonal coordinate system XYZ is attached. The Z-direction is for example a direction parallel to the vertical direction, and the +Z side is for example an upper part.

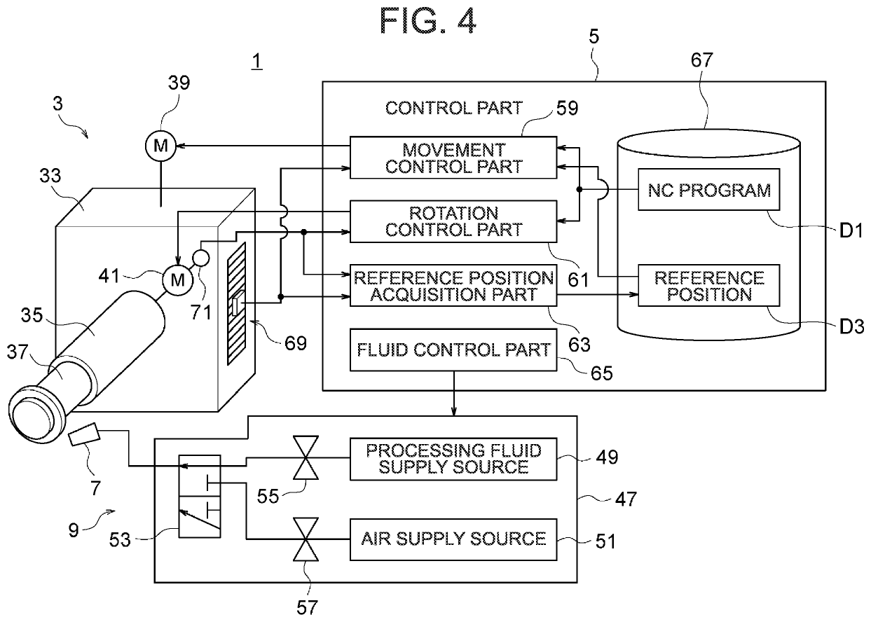

In the processing machine 1, a workpiece 103 is processed (for example cut) by a tool 101. The tool 101 and workpiece 103 are supported and driven by a machine body 3 shown in FIG. 1. The machine body 3 is controlled by a control part 5 (see FIG. 4). In the example shown, the tool 101 is a blade having a cutting edge on its outer periphery and is held by a spindle 37 parallel to the Y-direction. Further, the workpiece 103 is cut by the spindle 37 moving to the −Z side while rotating about the shaft center parallel to the Y-direction. Specifically, for example, although not particularly shown, a groove extending in the X-direction is formed in the upper surface of the workpiece 103. A processing fluid (not shown, for example cutting fluid) is supplied from a nozzle 7 to the region where processing is carried out.

The control part 5, for example, acquires as the reference position the position of the spindle 37 in the Z-direction at the time when the tool 101 is moved to the −Z side and the tool 101 abuts against the workpiece 103 (another member is possible as will be explained later). Further, the spindle 37 is moved to a relative position in the Z-direction set with respect to the reference position. Due to this, for example, the depth of the groove formed in the upper surface of the workpiece 103 can be made a desired size (relative distance between the reference position and the relative position).

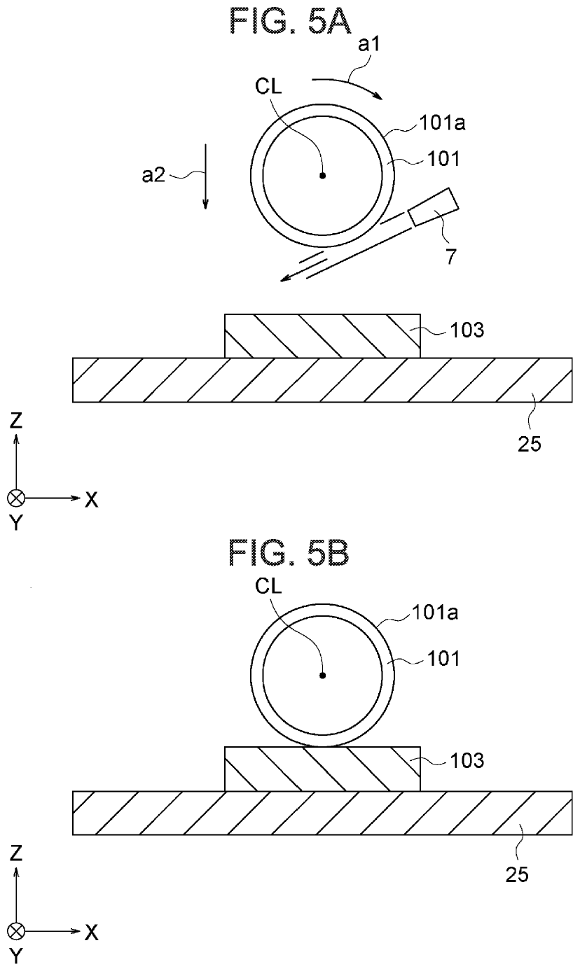

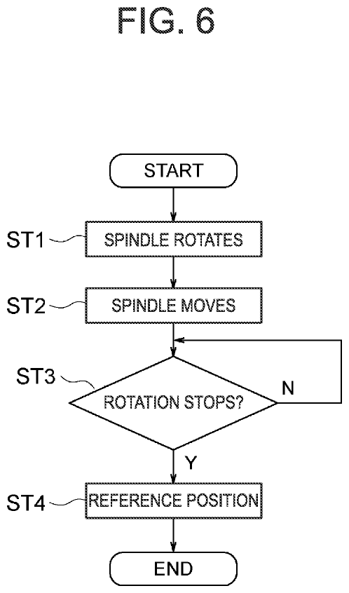

FIG. 5A and FIG. 5B are schematic views for explaining a method of acquisition of the information of the position serving as the reference position described above. FIG. 6 is a flow chart showing an example of the procedure of the method of acquisition of the information of the position serving as the reference position. Note that, FIG. 6 may be grasped as a flow chart showing an example of the procedure of processing executed by the control part 5 as well.

Note that, in the following explanation, for convenience, sometimes the information of the reference position will be simply referred to as the “reference position”. Further, sometimes acquisition of information of the position serving as the reference position will be referred to as acquisition of the reference position.

First, as indicated by an arrow a1 in FIG. 5A and step ST1 in FIG. 6, in a state where the tool 101 is separated from the workpiece 103 to the +Z side, the tool 101 (spindle 37 from another viewpoint) is rotated about a rotation axis CL. Further, as indicated by an arrow a2 in FIG. 5A and step ST2 in FIG. 6, in a state where the tool 101 is being rotated, the tool 101 is made to approach the workpiece 103.

The rotational speed of the tool 101 at this time is for example lower than the rotational speed of the tool 101 when cutting the workpiece 103 by the tool 101. From another viewpoint, the moment driving the tool 101 at this time (moment from outside and/or inertial moment; same is true for the following explanation) is smaller than the moment driving the tool 101 at the time of processing.

The method of rotating the tool 101 may be made various methods. In the example shown, the tool 101 is rotated by fluid being supplied from the nozzle 7 toward the outer periphery of the tool 101 in a tangential direction of the outer periphery.

After that, as shown in FIG. 5B, when the tool 101 abuts against the workpiece 103, the rotation of the tool 101 stops due to the frictional force etc. received by the tool 101 from the workpiece 103. As shown at step ST3 in FIG. 6, the control part 5 detect this cessation of rotation. Further, when detecting cessation of rotation (when it is judged YES at step ST3), as shown at step ST4, the control part 5 detects the position of the spindle 37 in the Z-direction at this time and determines this position in the Z-direction as the reference position.

In this way, in the present embodiment, contact of the tool 101 with respect to the workpiece 103 is detected based on the phenomenon of the rotating tool 101 abutting against the workpiece 103 and stopping. Accordingly, the tool 101 or the reference member (workpiece 103 here) which contacts the tool 101 need not have conductivity. Further, it is not necessary to use a pseudo blade as well. Further, if the rotational speed of the tool 101 is made low (if the moment is made small), the likelihood of deterioration of the tool 101 and/or reference member is lowered.

### (Details of Processing Machine)

As already explained, the processing machine 1 for example has the machine body 3 including the spindle 37 and the control part 5 which controls the machine body 3. Further, the processing machine 1 has a fluid supply part 9 including the nozzle 7 (see FIG. 4). The control part 5 may also be utilized for control of the fluid supply part 9. Further, the fluid supply part 9 may be grasped as a device different from the processing machine 1 unlike the above explanation.

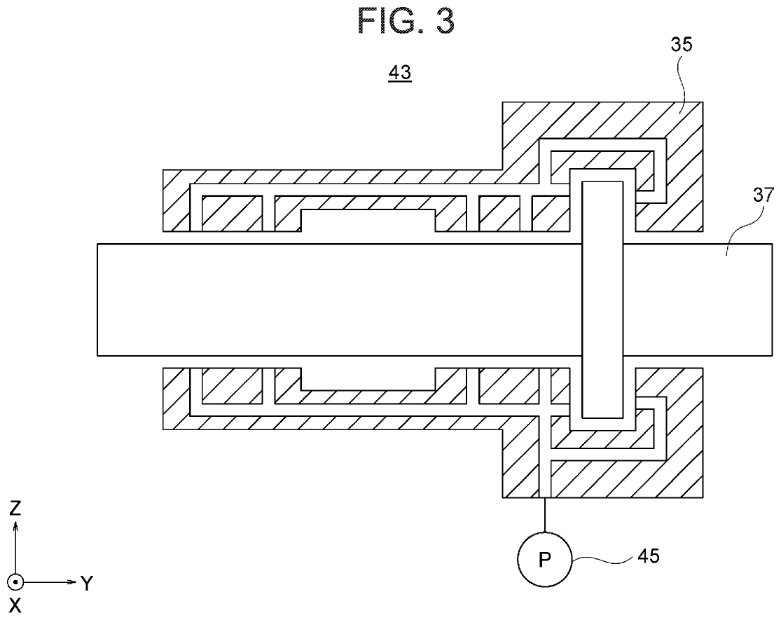

Below, the components etc. of the processing machine 1 will be schematically explained in order of the following list.
Tool 101 (FIG. 1 and FIG. 2)
Workpiece 103 (FIG. 1 and FIG. 2)
Machine body 3 (FIG. 1, FIG. 2, and FIG. 3)
Fluid supply part 9 (FIG. 1, FIG. 2 and FIG. 4)
Control part 5 (FIG. 4)
Procedure of acquisition of information of position which becomes reference position (FIG. 5A, FIG. 5B, and FIG. 6)
Summary of embodiment

### (Tool)

The tool 101 may be made various tools used for various processing. For example, the tool 101 may be made a cutting tool performing cutting, a grinding tool performing grinding, or a polishing tool performing polishing. The cutting tool may be for example a rotating tool (rotational tool) which rotates by itself to cut the workpiece 103 (example shown) or may be a turning tool which cuts the rotating workpiece 103. As the rotating tool, for example, there can be mentioned a milling tool, drill, and reamer. The grinding tool or polishing tool may be one using fixed abrasive grains fixed on the tool or may be one using free abrasive grains contained in a slurry.

Unlike the example shown, when acquiring the reference position in a mode where the tool 101 is a turning tool, for example, the turning tool and the workpiece 103 are made to approach each other in a state where the spindle holding the workpiece 103 is rotated. Further, cessation of rotation of the workpiece 103 due to contact of the two is detected. The position of the tool 101 or workpiece 103 which is detected at this time may be acquired as the reference position. Note that, without particular explanation, sometimes the present embodiment will be explained or expressed predicated on the tool 101 being a rotating tool as in the example shown.

Consider a situation in which processing is carried out by moving the tool 101 or workpiece 103 (tool 101 in the example shown) in the first direction (Z-direction in the example shown) and/or a situation in which the reference position in the first direction is acquired. At this time, in the tool 101, the part which contacts the workpiece 103 in the first direction may be any part. In other words, the relationship between the orientation of the tool 101 and the first direction may be any relationship. For example, in the mode where the tool 101 is a rotating tool, the above contacting part may be an outer peripheral part (outer side part around the rotation axis, example shown) or may be a front end part.

As in the example shown, in the mode where the outer peripheral part of the rotating tool contacts the workpiece 103 in the first direction, for example, when acquiring the reference position, the rotation of the tool 101 is apt to stop due to contact of the tool 101 with respect to the workpiece 103. This effect for example becomes higher as the diameter becomes larger. In regard to such a viewpoint, the diameter of the tool 101 for example may be 1 time or more, 2 times or more, or 5 times or more than the maximum length (maximum thickness from another viewpoint) of the tool 101 in the direction of the rotation axis.

In FIG. 1 and FIG. 2, as the tool 101, a rotating tool is illustrated. In more detail, the tool 101 in the example shown is a blade having a cutting edge 101a (notation is shown in FIG. 5A and FIG. 5B) on its outer periphery. The blade is substantially a plate shape having a circular outer edge (disk shape or ring shape). The blade is utilized for formation of a groove in the workpiece 103 and/or for cutting off (dividing) the workpiece 103 by rotating about its axis (in the example shown, about the rotation axis parallel to the Y-direction). The processing machine 1 may have one blade attached (example shown) or may have a plurality of blades spaced apart from each other in a direction parallel to the rotation axis attached. Note that, the following explanation, like in the example shown, sometimes will be predicated on a mode where one blade is attached.

### (Workpiece)

As will be understood from the above explanation of the case where various types of processing may be carried out by the tool 101, the workpiece 103 may also be made various ones. For example, the material of the workpiece 103 may be made various materials. It may be a metal, ceramic, resin, wood, chemical wood, or composite material (for example carbon fiber-reinforced plastic). The shape and dimensions of the workpiece 103 before processing and/or after processing may be any shape and dimensions. Also, the precision of dimensions demanded from the workpiece 103 after processing may be any precision. For example, when explaining an example of a case where relatively high precision is requested, the precision (allowance) may be made 10 μm or less, 1 μm or less, or 100 nm or less.

Consider a situation where the tool 101 or workpiece 103 (tool 101 in the example shown) is moved in the first direction (Z-direction in the example shown) and processing is carried out and/or the reference position in the first direction is acquired. At this time, in the workpiece 103, the part which contacts the tool 101 in the first direction may be any part. From another viewpoint, the relationship between the orientation of the member holding the workpiece 103 (in the example illustrated, the later explained table 25) and the first direction may be any relationship.

For example, in the mode where the tool 101 is a rotating tool (example shown), the above contacting part may be the upper surface (surface on the side opposite to the table 25) of the workpiece 103 (example shown) or may be a side surface (surface which faces the lateral side of the table 25) of the workpiece 103 unlike the example shown. Further, although not particularly shown, in the mode where the tool 101 is a turning tool, the above contacting part may be the outer peripheral surface (outer side surface around the rotation axis) of the workpiece 103 or may be an end face (surface which faces a direction parallel to the rotation axis).

In FIG. 1 and FIG. 2, as the workpiece 103, a plate-shaped one (base plate) is illustrated. The shape of the plate-shaped workpiece 103 before processing may be any shape. For example, it is box shape (example shown) or circular shape. In the mode as already explained in which the tool 101 is a disk-shaped blade having a cutting edge 101a on its outer periphery, the blade for example contributes to formation of a groove which extends in a direction (X-direction) perpendicular to the rotation axis of the tool 101 in the upper surface (surface on the +Z side) of the plate-shaped workpiece 103 or division of the workpiece 103 in the Y-direction.

### (Machine Body)

The explanation of the machine body 3 will be given schematically in the following order.
Overview of machine bodies 3 able to be utilized in the present embodiment
Machine body 3 illustrated in FIG. 1
One example of configuration of bearing of spindle 37

### (Overview of Machine Bodies)

The machine body 3 supports and drives the tool 101 and workpiece 103. That is, the machine body 3 is responsible for the main part of the processing. The configuration of the machine body 3 may be configured in various ways. For example, it may be made a known configuration.

For example, regarding the machine performing the processing, sometimes a machine tool and an industrial robot will be differentiated from each other (boundary between these not always clear). In a case differentiated in such a way, the machine body 3 (or processing machine 1) may be one classified as either of the two. Note that, in the explanation of the present embodiment, the mode where the machine body is generally classified as a machine tool will be taken as an example.

Further, for example, as will be understood from the explanation of the tool 101 already given, the processing aimed at by the machine body 3 (or processing machine 1) may be made cutting, grinding and/or polishing, and other various ones. Further, the machine body 3 performing cutting etc. may be one rotating the tool 101 or may be one rotating the workpiece 103.

The machine body 3 may or may not be a multi-tasking machining tool. The machine body 3 may be one driving one tool 101 (example shown) or may be a multi-spindle or multi-head type which simultaneously drives a plurality of tools 101. The machine body 3 (processing machine 1) rotating the tool 101 (rotating tool) may be for example a milling machine, drilling machine, boring machine, or machining center.

In the machine body 3, for example, the tool 101 and the workpiece 103 are moved relative to each other on each of an X-axis, Y-axis, and Z-axis perpendicular to each other. The machine body 3 may be one able to make the tool 101 and the workpiece 103 relatively move on another axis as well in addition to the above three axes. For example, the machine body 3 (processing machine 1) may be one able to rotate about at least one axis parallel to any of the above three axes (for example, a 5-axis machining center) as well. As will be understood from the known machining tool, the relative movements of the tool 101 and the workpiece 103 on the axes may be realized by movement of the tool 101 or may be realized by movement of the workpiece 103.

Note that, in the explanation of the present embodiment, basically, the orientations of the spindle 37, table 25, and other various members will be explained predicated on the orientations of the various members not changing. In the mode where the orientations of the members can change, this explanation, for example, may be applied to the standard orientations of the members or may be applied to specific orientations different from the standard orientations. The standard orientations may be reasonably judged with reference to common technical knowledge.

In the mode where the tool 101 is a rotating tool, the relative relationships among the orientation of the spindle 37, the orientation of the table 25, the vertical direction, and the first direction (Z-direction in the example shown) at which the reference positions are acquired may be any relationships. In the same way, in a mode where the tool 101 is a turning tool, the relative relationships among the orientation of the spindle 37, the orientation of a toolpost, the vertical direction, and the first direction may be any relationships.

For example, the spindle 37 (its rotation axis) may be parallel with respect to the upper surface of the table 25 (example shown) or may cross it (for example, be perpendicular). Further, the first direction may cross the spindle 37 (for example, be perpendicular, example shown) or may be parallel with it. The first direction may cross the upper surface of the table 25 (for example, be perpendicular, example shown) or may be parallel with it.

### (Machine Body in Example Shown)

In FIG. 1, as the machine body 3, a slicer able to perform cutting by rotating a disk-shaped tool 101 having a cutting edge 101a on its outer periphery is illustrated.

Specifically, for example, the machine body 3 illustrated in FIG. 1, has the following components as the components supporting the workpiece 103: a base 21 set on a floor surface in a factory or the like; an X-axis bed 23 fixed onto the base 21; a table 25 which is supported upon the X-axis bed 23 and is able to move in the X-direction (horizontal direction); and a chuck 27 which is fixed onto the table 25 and detachably holds the workpiece 103. Although not particularly shown, the machine body 3 may be configured so as to be able to rotate the table 25 about an axis parallel to the Z-axis as well.

Further, for example, the machine body 3 illustrated in FIG. 1 has the following components as the components supporting and driving the tool 101; the base 21; a Y-axis bed 29 which is fixed onto the base 21; z Y-axis movement part 31 which is supported upon the Y-axis bed 29 and is able to move in the Y-direction (horizontal direction); a Z-axis movement part 33 which is supported upon the Y-axis movement part 31 and is able to move in the Z-direction (vertical direction); a spindle head 35 (not including the spindle 37) fixed to the Z-axis movement part 33; a spindle 37 (notation is shown in FIG. 2) which is supported by the spindle head 35 so as to be able to rotate about a rotation axis parallel to the Y-direction and detachably holds the tool 101.

A driving force from a not shown drive source (for example electric motor) is transmitted to the table 25 to move the table 25 in the X-direction. Due to this, the workpiece 103 supported upon the table 25 moves in the X-direction relative to the tool 101. A driving force from a not shown drive source (for example electric motor) is transmitted to the Y-axis movement part 31 to move the Y-axis movement part 31 in the Y-direction. Due to this, the tool 101 supported upon the Y-axis movement part 31 moves in the Y-direction relative to the workpiece 103. A driving force from a predetermined drive source (for example a Z-axis electric motor 39 shown in FIG. 4 which will be explained later) is transmitted to the Z-axis movement part 33 to move the Z-axis movement part 33 in the Z-direction. Due to this, the tool 101 supported upon the Z-axis movement part 33 relatively moves in the Z-direction relative to the workpiece 103. A driving force from a predetermined drive source (for example a spindle motor 41 shown in FIG. 4) is transmitted to the spindle 37 to rotate the spindle 37 about the axis. Due to this, the tool 101 held by the spindle 37 is rotated about the axis.

FIG. 1 and FIG. 2 are schematic views. The shapes of the members (21, 23, 25, 27, 29, 31, 33, 35, and 37) shown in the views are just schematic ones. The shapes of the members in actuality may be greatly different from the shown shapes. Further, the materials of the members may also be any materials. Further, a guide (notation is omitted) which guides the movement part (25, 31, or 33) moving parallel with respect to the support part (23, 29, or 31) is only schematically shown, too. It may be different from the shape shown etc. as well.

The guide which guides the movement part (25, 31, or 33) moving parallel with respect to the support part (23, 29, or 31) may be made a suitable one. For example, the guide may be a sliding guide by which the support part and the movement part slide, may be a rolling guide by which a roller rolls between the support part and the movement part, may be a hydrostatic guide by which air or oil is interposed between the support part and the movement part, or may be a combination of two or more of them. In the same way, the bearing of the spindle 37 may be made a sliding bearing, rolling bearing, hydrostatic bearing, or combination of two or more of them.

The drive source concerned with the parallel movement is for example an electric motor. This electric motor may be rotary one or may be a linear motor. The rotation movement of the rotary electric motor may be converted to a linear motion according to a suitable mechanism such as screw mechanism (for example ball screw mechanism). Further, the drive source concerned with the parallel movement may be made a hydraulic type (oil pressure type) or pneumatic type. In the same way, the drive source concerned with the rotation of the spindle 37 is for example a rotary electric motor (spindle motor 41). However, the drive source related with the rotation of the spindle 37 may be made a hydraulic type (oil pressure type) or pneumatic type. The specific configurations of the various electric motors may be made various ones. The electric motor may be a DC motor or may be an AC motor. The AC motor may be a synchronous motor or may be an induction motor.

The rotor (not shown) of the spindle motor 41 and the spindle 37 are fixed to each other (including a mode where parts are shared with each other) so that they rotate together. However, between the rotor (part or entirety) and the spindle 37, a clutch and/or transmission or the like may be interposed as well. When a clutch is interposed, in an operation for acquiring the reference position, the connection of the rotor and the spindle 37 may be disengaged and thereby the inertial moment may be made smaller. Note that, the explanation of the present embodiment, unless particularly explained otherwise, will be given and expressed predicated on a mode where the rotor and the spindle 37 integrally rotate.

In the mode where the spindle motor 41 is a synchronous motor including permanent magnets, for example, when electric power is not supplied resulting in a torque-free state, an attraction force stopping rotation of the spindle 37 is generated. Accordingly, for example, when acquiring the reference position, the likelihood of occurrence of unwanted rotation is reduced. Further, from another viewpoint, rotation by supply of fluid to the tool 101 is effective. On the other hand, in the mode where the spindle motor is an induction motor, for example, when electric power is not supplied resulting in a torque-free state, an attraction force stopping rotation of the spindle 37 is not generated. Accordingly, for example, even if the force given to the tool 101 by a fluid is made small, the spindle 37 can be rotated.

The chuck 27 is for example configured by a vacuum chuck or electrostatic chuck and is attached to the table 25 by a machine vise (not shown) or another suitable device. Note that, the chuck 27 may also be configured integrally and inseparably with respect to the table 25 unlike in the above explanation. Further, the chuck 27 need not be provided, and the workpiece 103 may be fixed to the table 25 by a suitable fixture (for example machine vise) different from the chuck 27.

Unlike the explanation of the present embodiment, the combination of the table 25 and the chuck 27 may be grasped as the table as well. When referring to the “holding surface of the table which holds the workpiece 103”, the holding surface may be a holding surface 25a (notation shown in FIG. 2) of the table 25 indirectly holding the workpiece 103 by holding the chuck 27 or may be a holding surface 27a (notation shown in FIG. 2) of the chuck 27 directly holding the workpiece 103.

The spindle 37 may hold the tool 101 by a mechanism (for example clamp mechanism) provided at itself, or the tool 101 may be attached by a device including screws etc. The blade (tool 101), for example, although not particularly shown, may be fixed to the spindle 37 by a member having a shaft part inserted through a hole formed at the center of the blade, a member which is superposed on the blade in the axial direction of the spindle 37, and a screw which is inserted through these members and is screwed with the spindle 37. In such a mode, the blade may be grasped as the tool 101, or the entireties of the blade and the device for attaching the blade to the spindle 37 may be grasped as the tool 101.

The spindle 37 is positioned on the side which the holding surface 27a of the table 25 faces. Its rotation axis runs along the holding surface 27a (for example parallel to it). Further, by the spindle 37 moving in the Z-direction embodying the first direction, the outer peripheral part of the blade embodying the tool 101 contacts the upper surface of the workpiece 103 whereupon processing or acquisition of the reference position is carried out.

### (One Example of Configuration of Bearing of Spindle)

As already explained, the bearing of the spindle 37 may be configured in any way. Here, as one example of the bearing of the spindle 37, the configuration of a hydrostatic bearing will be explained.

FIG. 3 is a schematic cross-sectional view showing one example of the configuration of the bearing 43 in the spindle 37 and corresponds to the III-III line in FIG. 2.

A gap is formed between the outer circumferential surface of the spindle 37 and the inner circumferential surface of the spindle head 35. A gas (for example air) or liquid (for example oil or water) is supplied to the gap at a predetermined pressure by a pump 45 or the like. Note that, in the former mode, the bearing 43 is an air bearing.

### (Fluid Supply Part)

FIG. 4 is a block diagram showing the configuration of the processing machine 1 focusing on the configuration of a signal processing system.

The fluid supply part 9 has the nozzle 7 and a supply part body 47 which supplies the fluid to the nozzle 7. The fluid supply part 9, as already explained, supplies the processing fluid from the nozzle 7 to a region where processing is carried out (below, sometimes referred to as the “processing region”) when the workpiece 103 is processed by the tool 101. Further, the fluid supply part 9 rotates the tool 101 by supplying the fluid from the nozzle 7 toward the tool 101 when acquiring the reference position.

Below, schematically, the explanation will be given in the following order.
Processing fluid
Fluid supplied when acquiring reference position
Member to which fluid is ejected when acquiring reference position
Nozzle 7
Supply part body 47

### (Processing Fluid)

As will be understood from the already given explanation of the tool 101, the processing fluid (not shown) may be made various fluids utilized for various processing. For example, in the mode where the processing is cutting, the processing fluid may be made a cutting fluid (in another expression, cutting oil). The principal ingredient of the cutting fluid may be oil or may be water. Further, the processing fluid may be made for example a grinding fluid for grinding or a polishing fluid for polishing. The grinding fluid or polishing fluid (slurry) need not contain free abrasive grains or may contain those. Whatever the processing, the processing fluid may be made simply water as well. Further, the processing fluid may be a coolant aimed at only cooling or mainly aimed at cooling.

(Fluid Supplied when Acquiring Reference Position)

In the operation for acquiring the reference position, the type (ingredient) of the fluid which is supplied to the tool 101 in order to make the tool 101 rotate may be any type. For example, the fluid may be a processing fluid may be a fluid different from the processing fluid or may be a gas. As the gas, for example, there can be mentioned air and an inert gas (for example nitrogen). In the explanation of the present embodiment, basically a mode of supply of air will be taken as an example. Further, unless particularly indicated otherwise, sometimes the explanation will be given predicated on the fluid supplied for acquisition of the reference position being air.

(Member which Fluid is Made to Strike when Acquiring Reference Position)

In the explanation given up to here, the member which the fluid is made to strike for the spindle 37 rotate in the operation for acquiring the reference position was the tool 101. However, in the mode where that the workpiece 103 is held upon the spindle 37, the member which the fluid is made to strike may be made the workpiece 103. Note that, in any mode, the member which the fluid is made to strike can be said to be the rotation target held upon the spindle 37.

Further, whether the rotation target is the tool 101 or the workpiece 103, the fluid may be made to strike the spindle 37 in place of or in addition to the rotation target. A member for enlarging the moment by the fluid striking it may be attached to the spindle 37 as well. Such a member may be grasped as a part of the spindle 37 or a part of the rotation target.

The fluid is made to strike the outer surface of the rotation target (tool 101 or workpiece 103) or the outer surface which is exposed to the outside of the spindle 37. The qualification “exposed to the outside of the spindle 37” is made for differentiation from the technique of giving a moment to the spindle 37 by the fluid inside the spindle head 35 for processing (technique using fluid in place of the spindle motor 41).

Note that, the explanation of the present embodiment sometimes will be expressed predicated on the member which the fluid is made to strike in order to realize the rotation of the spindle 37 in the operation for acquiring the reference position is the tool 101. The term “tool 101” embodying the member which the fluid is made to strike may be suitably replaced by the term “workpiece 103” or “spindle 37” unless a contradiction etc. arises.

### (Nozzle)

The nozzle 7 shown in FIG. 2 supplies the processing fluid to the processing region when the workpiece 103 is processed by the tool 101. The processing region, in other words, is a region in the workpiece 103 where the processing is carried out by the tool 101. For example, in a mode where the tool 101 is one performing cutting, the processing region is the position at which the cutting edge abuts against the workpiece 103 and its adjacent region. In a mode where the tool 101 is one performing grinding and polishing, for example, the processing region is the abutting position of the tool 101 and the workpiece 103 and its adjacent region or the abutting region. The abutting may be an indirect one through free abrasive grains as well.

The processing fluid may be supplied to the processing region in various ways. For example, the nozzle 7 may make the processing fluid flow out toward the processing region or may make the processing fluid flow out toward a position separated from the processing region in the tool 101 or workpiece 103 so as to make the processing fluid arrive at the processing region through the tool 101 or workpiece 103. The nozzle 7 may eject the processing fluid or may make the processing fluid flow out at a flow velocity not describable as “ejection”. The nozzle 7 may make the processing fluid flow out (for example eject it) as a single flow having a suitable cross-section or may make the processing fluid flow out (for example eject it) in a shower state or may eject the processing fluid in a mist state.

Further, the nozzle 7, when acquiring the reference position, ejects the fluid by an orientation giving a moment around the rotation axis of the spindle 37 to the outer surface of the tool 101. The position (region) in the tool 101 which the fluid is made to strike when the spindle 37 is made to rotate in this way may be made various positions. Further, the direction in which the fluid is made to strike the above position (from another viewpoint, the direction in which the fluid is ejected) may be made various directions. Conceptually, for example, so far as an imaginary line extending from the operating point of the resultant force of the forces exerted upon the tool 101 by the fluid in the direction of the resultant force is separated from the rotation axis, the tool 101 can rotate. In other words, if the fluid is made to strike the outer surface of the tool 101 off from the rotation axis of the tool 101, the tool 101 rotates.

Specifically, for example, when the tool 101 is viewed parallel to its rotation axis, the direction in which the fluid is made to strike may be made a direction in which an imaginary line, which extends from the position which the fluid strikes (or region or center position of the region) in the direction in which the fluid is made to strike, is separated from the rotation axis of the spindle 37. Note that, this direction can be considered as a tangential direction of a circle having any radius about the rotation axis. Further, for example, when the tool 101 is viewed parallel to its rotation axis, the direction in which the fluid is made to strike may be made the tangential direction of a circle passing through the position which the fluid is made to strike. Note that, the tangential direction relating to the direction in which the fluid is made to strike (and/or the direction in which the fluid is ejected) may include a relatively large permissible difference. For example, it may be not larger than the range of 60° or range of 30° about a strict tangential direction.

Further, for example, the direction in which the fluid is made to strike may be perpendicular to the rotation axis of the tool 101 with a relationship of skew lines or may be inclined in a direction parallel to the rotation axis (Y-direction in the example shown). Further, for example, the position in which the fluid is made to strike may be the outer peripheral part of the tool 101 (outer side part around the rotation axis) or may be the surface of the tool 101 which faces a direction along the rotation axis (+Y side and/or −Y side surface in the example shown) or may be both of the former and the latter.

When the fluid which is made to strike the tool 101 in order to make the spindle 37 rotate is a liquid, the mode when the fluid is ejected from the nozzle 7 may be made various modes. For example, the explanation for the modes of supply in the explanation of supply of the processing fluid (the mode of being ejected as a single flow and the mode of being ejected in a shower state and the like) may be cited for the modes of supply of the fluid for rotation. Further, when the fluid is a liquid, the liquid may be supplied to the tool 101 by a mode not able to be called “ejection” and the tool 101 may be rotated by utilizing a force due to the liquid falling.

The configuration of the nozzle 7 may be made various configurations. For example, it may be made the same as a known configuration. The configurations of the nozzle for realizing the modes at the time of outflow of the liquid (the mode of being ejected as a single flow and the mode of being ejected in a shower state and the like) are known. Further, the nozzle 7 may be one able to switch the mode when making the fluid flow out or may be one unable to switch it. In the former case, the switching state of the nozzle 7 may be the same or may be different between the time when the processing fluid is supplied and the time when fluid is supplied in order to make the spindle 37 rotate.

The configuration relating to the attachment and positioning etc. of the nozzle 7 may be made various configurations. For example, it may be made the same as a known configuration. Specifically, for example, the nozzle 7 may be made detachable with respect to the machine body 3. Note that, in this case, in the same way as the tool 101 and workpiece 103, the nozzle 7 may be grasped as an element different from the processing machine 1 as well. The nozzle 7 may be able to move during the processing or may be arranged at a constant position. The positioning of the nozzle 7 with respect to a predetermined element (for example spindle 37) may be carried out manually or may be carried out by a robot. In the latter case, the positioning may be automatically carried out by the control part 5 or may be carried out according to an operation with respect to a not shown operation part provided in the processing machine 1. In a mode where the position of the nozzle 7 can be changed, the position of the nozzle 7 may be the same or may be different between the time when the processing fluid is supplied and the time when fluid is supplied in order to make the spindle 37 rotate in the operation for acquisition of the reference position.

In the example shown in FIG. 2, the nozzle 7 is positioned at the front end of a bellows (notation is omitted) able to maintain its shape. The end part of the bellows on the side opposite to the nozzle 7 is connected to a block (notation is omitted) having a flow passage. The block is fixed to the spindle head 35 by a suitable device. Accordingly, the nozzle 7 is able to relatively move together with the tool 101 relative to the workpiece 103 (excluding rotation about the axis of the tool 101). Further, the specific position and orientation are determined by making the bellows deform by manual operation. In FIG. 2, the nozzle 7 is positioned so that the processing fluid and the fluid for making the spindle 37 rotate strike the cutting edge 101a of the blade embodying the tool 101 in the tangential direction of the cutting edge 101a.

### (Supply Part Body)

The supply part body 47 has a processing fluid supply source 49 which supplies the processing fluid and an air supply source 51 which supplies fluid (here, air) for making the spindle 37 rotate when acquiring the reference position. Further, the supply part body 47 has a control valve 53 which selectively connects the processing fluid supply source 49 and the air supply source 51 with respect to the nozzle 7. Due to this, the fluid supply part 9 becomes able to selectively make the processing fluid and air flow out from the nozzle 7.

In the supply part body 47, the supply system of the processing fluid may be suitably configured in accordance with the type of processing fluid etc. For example, in the mode where the processing fluid is a cutting fluid, grinding fluid, or polishing fluid, the supply system of the processing fluid may be configured the same as the configuration of the device supplying the processing fluid in a usual machining tool or may be made a configuration applying this. Further, in the mode where the processing fluid is water, the supply system of the processing fluid may be configured so as to be supplied with water from equipment in a factory, and to have a valve which permits or prohibits supply of water to the nozzle 7.

In the mode where the processing fluid is a cutting fluid, grinding fluid, or polishing fluid or something similar to them, the processing fluid supply source 49, for example, although not particularly shown, may have a tank storing the processing fluid and a pump which sends out the processing fluid from the tank. The supply system of the processing fluid may have a valve which controls the flow of the processing fluid at a suitable position (for example a position between the pump and the control valve 53). In FIG. 4, a processing fluid-use valve 55 which is opened/closed in response to a command from the control part 5 is illustrated. Further, by the pump and/or processing fluid-use valve 55, any supply of the processing fluid, the flow rate of the processing fluid and/or the pressure of the processing fluid may be controlled.

In the supply part body 47, the supply system of air may be suitably configured. For example, as the supply device of the processing fluid, one ejecting a mist of the processing fluid by mixing the processing fluid and compressed air is known. The configuration for supplying the compressed air may be applied to or may be used also for the supply system of air. The air supply source 51, for example, although not particularly shown, may have a compressor which sends out the air. The supply system of air may have a valve controlling the flow of the air at a suitable position (for example a position between the compressor and the control valve 53). In FIG. 4, an air-use valve 57 which is opened/closed in response to a command from the control part 5 is illustrated. Further, by the compressor and/or air-use valve 57, any supply of air, the flow rate of the air and/or the pressure of the air may be controlled.

Note that, in a case where the fluid for making the spindle 37 rotate in the operation for acquisition of the reference position is a liquid, the explanation of the supply system of the processing fluid may be cited for the supply system of the liquid unless any contradictions arise. Further, in a case where the fluid for the spindle 37 rotate is a processing fluid, for example, the supply system for supplying the processing fluid at the time of processing may be utilized for supply of the processing fluid in the operation for acquiring the reference position. In other words, a supply system different from the supply system of the processing fluid and control valve 53 need not be provided.

The control valve 53 may be configured in any way. In FIG. 4, for convenience, as the control valve 53, the notation of a 3-port 2-position switching valve is shown. However, the control valve 53 may be a valve of another type as well. For example, the control valve 53 may be able to prohibit flow of both of a processing fluid and air. The control valve 53 may have a function of a flow rate control valve or pressure control valve. The control valve 53 is opened/closed in response to a command from the control part 5.

Note that, the control valve 53, processing fluid-use valve 55, and air-use valve 57 as a whole may be grasped as a single valve as well. Further, the control valve 53 may be omitted, and the processing fluid and the air may be selectively supplied to the nozzle 7 by the processing fluid-use valve 55 and air-use valve 57 as well. Conversely, the processing fluid-use valve 55 and air-use valve 57 may be omitted by the control valve 53 being able to prohibit flow of both of the processing fluid and air.

In the explanation of the present embodiment, the fluid supply part 9 is grasped as a part of the processing machine 1. In such a case, the fluid supply part 9, in appearance, may be provided in a way able to be grasped as a part of the processing machine 1 or may be provided in a way unable to be grasped in that way. For example, part or all of the fluid supply part 9 may be accommodated together with the machine body 3 shown in FIG. 1 in a not shown housing or may be accommodated in a housing separately from the machine body 3. Part or all of the fluid supply part 9 may be arranged in the base 21 or on the base 21 in the machine body 3.

### (Control Part)

The control part 5 shown in FIG. 4 may be for example configured including a computer. The computer, for example, although not particularly shown, is configured including a CPU (central processing unit), ROM (read only memory), RAM (random access memory), and external storage device. In FIG. 4, the RAM and/or external storage device is shown as a storage part 67. By the CPU running the program stored in the ROM and/or external storage device, various function parts (59, 61, 63, and 65) performing control etc. are constructed. Note that, the control part 5 may include a logical circuit performing only certain processing as well.

The control part 5 is a representation of the control parts of the processing machine 1 as a whole. The control part 5 may be provided at one position concentrated in terms of hardware or may be provided at a plurality of positions dispersed. When explaining the latter example, the control part performing control of the machine body 3 and the control part performing control of the fluid supply part 9 may be provided separately in terms of hardware. The two may perform control synchronously or need not perform such control. Synchronization may be realized by one operating based on a signal from the other or may be realized by provision of a higher level control part of the two.

The control part 5 has, as function parts performing control etc., function parts controlling the machine body 3 (59, 61, and 63) and the fluid control part 65 controlling the fluid supply part 9. The former, in more detail, include a movement control part 59 which controls relative movements of the spindle 37 and the table 25 at the time of processing, a rotation control part 61 which controls rotation of the spindle 37 at the time of processing, and a reference position acquisition part 63 which controls the operation at the time of acquisition of the reference position. Note that, these various function parts may be partially shared as well.

The movement control part 59, for example, controls the drive sources driving the movement parts (25, 31, or 33) on the different axes (for example X-axis, Y-axis, and Z-axis) based on detection values of the position sensors which detect the positions of the movement parts. Note that, position sensors need not be provided for the other axes besides the axis relating to the first direction (Z-axis in the example shown) in which the reference position is acquired. From another viewpoint, feedback control based on a position sensor need not be carried out for the other axes, but open loop control may be carried out.

In FIG. 4, in the configurations relating to three axes, the configuration for controlling the Z-axis electric motor 39 based on a Z-axis position sensor 69 detecting the position in the Z-direction of the Z-axis movement part 33 is illustrated. The “position in the Z-direction of the Z-axis movement part 33” referred to here is for example the position in the Z-direction in an absolute coordinate system (from another viewpoint, machine coordinate system). More strictly speaking, it is the position in the Z-direction relative to a member which is intended to be unmovable in the Z-direction (for example Y-axis movement part 31).

The above position sensors may be ones which directly detect the positions of the movement parts (example shown) or may be ones which detect the amounts of operation of the drive sources which drive the movement parts (for example amounts of rotation of rotary electric motors). From another viewpoint, feedback control based on the detection values of the position sensors may be full-closed loop (example shown) or may be semi-closed loop. The specific configurations of the position sensors may be made various configurations. For example, they may be made linear encoders (example shown) or laser measurement units. The linear encoders may be made optical types or magnetic types. Further, they may be made absolute types or incremental types.

The rotation control part 61 controls the spindle motor 41 which drives the spindle 37 based on the detection value of the rotation sensor 71 which detects the rotation of the spindle 37 (in more detail, for example rotational speed). The rotation sensor 71 may be one directly detecting the rotation of the spindle 37 or may be one detecting the rotation of the spindle motor 41. Further, differentiation as described above may be impossible due to parts of the spindle 37 and the spindle motor 41 being shared with each other. The specific configuration of the rotation sensor 71 may be made various configurations. For example, it may be made an encoder or resolver. The encoder may be made an optical type or magnetic type. Further, it may be made an absolute type or incremental type.

The control by the movement control part 59 and the rotation control part 61 is for example carried out according to an NC program D1 stored in the storage part 67 (RAM and/or external storage device). The NC program D1 for example prescribes one or more values relating to at least one type among the absolute coordinates (machine coordinates) of the target position, relative coordinates of the target position, target movement amount, rotational speed of the target, and the like. Further, the movement control part 59 and rotation control part 61 control the drive sources (39 and 41 etc.) based on the detection values of the position sensors (69 etc.) and the rotation sensor 71 so that the above various target values are realized.

Information D3 of the reference position acquired is stored in the storage part 67 (RAM and/or external storage device). The information D3 is suitably utilized in the control carried out according to the above NC program D1. The mode of utilization may be made various ones.

For example, relating to the Z-direction, the NC program D1 may include a program (one or more blocks) for making the spindle 37 (tool 101) move to a relative position (target position) set with respect to the reference position. Due to this, the reference position may be utilized.

The relative position relative to the reference position may be prescribed in one or more blocks by the relative coordinates with respect to the reference position or may be prescribed by the amount of movement from the reference position. Further, movement to the relative position in the Z-axis direction may be accompanied by movement in another axis or may not be accompanied by that.

In the above such mode of utilization, the relationship between movement based on the reference position and the processing content may be any relationship. Explaining one example, a groove may be formed with a predetermined depth by movement of the blade (tool 101) to the −Z side toward a relative position which is set further to the −Z side than the reference position from the reference position or from a relative position which is set further to the +Z side than the reference position. That is, the reference position may be utilized as the position for prescribing the amount of cutting from the upper surface of the workpiece 103.

Unlike the above, the reference position may also be utilized in a way where the reference position is not prescribed in the NC program. For example, the reference position may be utilized for detecting deviation between an actual position of the tool 101 and/or workpiece 103 and the position of the tool 101 and/or workpiece 103 which is supposed in the machine coordinates and for correcting all machine coordinates prescribed in the NC program or all positions detected by the position sensors. Note that, such a mode of utilization can be grasped as movement of the spindle 37 to the relative position set with respect to the reference position after all.

The reference position acquisition part 63 controls the machine body 3 (in more detail, the Z-axis electric motor 39) and the fluid supply part 9 so as to realize the operation for acquiring the reference position. In FIG. 4, illustration of the arrow representing this control is omitted. The reference position acquisition part 63, in the control of the Z-axis electric motor 39, may utilize the movement control part 59 and may control the fluid control part 65 in the control of the fluid supply part 9. From another viewpoint, the reference position acquisition part 63 may be partially shared with the movement control part 59 and fluid control part 65.

The reference position acquisition part 63 obtains the position of the spindle 37 in Z-axis direction when cessation of rotation of the spindle 37 is detected as the reference position. The sensor detecting the position of the spindle 37 at this time is, for example, the Z-axis position sensor 69 used by the movement control part 59 for feedback control. This ensures that the reference position and the relative position set with respect to that reference position are determined based on detection values from the same sensor, leading to an improvement in machining accuracy.

Although not particularly shown, the operation routine for acquiring the reference position, for example, unlike the operation routine at the time of processing, is prescribed by a program different from the NC program. The other program is for example included in the program executed by the CPU for constructing the reference position acquisition part 63. The program for constructing the reference position acquisition part 63 may be stored in advance in the storage part 67 by the manufacturer of the processing machine 1 or may be installed in the already existing processing machine 1 by an operator. Unlike the above explanation, a part of the operation procedures for acquiring the reference position may be prescribed by a program prepared in the same way as the NC program as well.

The sensor which detects cessation of rotation may be the rotation sensor 71 (example shown) which is utilized by the rotation control part 61 for the feedback control or may be another sensor. In the former mode, for example, the configuration is simplified. In the latter mode, for example, a sensor able to detect a further smaller change of the rotation angle than the rotation sensor 71 is provided, therefore cessation of rotation can be detected with a high precision. Note that, the explanation of the present embodiment, for convenience, will be sometimes given predicated on the former mode.

The fluid control part 65, for example, controls the fluid supply part 9 so that the processing fluid is supplied at the time of processing and air is supplied at the time of acquisition of the reference position. Specific control targets of that are for example the control valve 53, processing fluid-use valve 55, air-use valve 57, processing fluid supply source 49 (for example not shown pump), and air supply source 51 (for example not shown compressor).

### (Acquisition Procedures of Reference Position)

Outline for FIG. 5A, FIG. 5B, and FIG. 6 is as already explained.

The operation for acquisition of the reference position shown in these views may be started at the time when the operator performs a predetermined operation with respect to a not shown operation part provided in the processing machine 1 or may be automatically started by the control part 5 without relying on operation by the operator. In the latter mode, as the timing of automatic acquisition of the reference position by the control part 5, for example, there can be mentioned the time when a series of processing prescribed by the NC program is started, the time when special processing in the above series of processing is started, and the time when an amount of wear exceeds a predetermined threshold value by a not shown sensor detecting wear of the tool 101.

When acquiring the reference position, the control part 5 controls the fluid supply part 9 and blows air from the nozzle 7 to the tool 101. Further, at this time, the control part 5 for example sets the spindle motor 41 to a torque-free state. That is, electric power is not supplied to the spindle motor 41. Due to this, the spindle 37 rotates as indicated by the arrow a1. Further, the control part 5 controls the Z-axis electric motor 39 and moves the spindle 37 toward the table 25 as indicated by the arrow a2.

In the operation for acquiring the reference position, the rotation of the spindle 37 and the movement of the spindle 37 may be simultaneously started or one may be started earlier than the other. Further, air may be continuously ejected from the nozzle 7 until cessation of rotation of the spindle 37 is detected or may stop being ejected before cessation of the rotation of the spindle 37 is detected. In the former mode, for example, the spindle 37 can be reliably made to rotate until the rotation of the spindle 37 is stopped due to contact of the spindle 37 with the workpiece 103. In the latter mode, for example, by making the rotational speed of the spindle 37 when the spindle 37 contacts the workpiece 103 low, the likelihood of deterioration of the tool 101 and/or workpiece 103 can be reduced.

The rotational speed of the spindle 37 (from another viewpoint, the pressure of air or the like) when acquiring the reference position may be made a suitable one. For example, the rotational speed at this time may be sufficiently lower than the rotational speed when performing processing by the tool 101. From another viewpoint, the inertial moments of the spindle 37 and tool 101 and/or moment which is given to the tool 101 by air may be made smaller than that at the time when processing is carried out.

The specific rotational speed or moment in the processing or acquisition of the reference position may be suitably set in accordance with the specific configuration of the machine body 3, the type of the tool 101, the type of the workpiece 103, and the like to which the present embodiment is applied. When explaining one example, the rotational speed in the processing (in more detail, for example, immediately before the tool 101 contacts the workpiece 103 or at the time of the contact) is 2000 rpm (rotations per minute) or more. On the other hand, the rotational speed in the operation for acquiring the reference position (in more detail, for example, immediately before the tool 101 contacts the workpiece 103) is 100 rpm or less or 10 rpm or less. From another viewpoint, the rotational speed in the operation for acquiring the reference position may be made 1/10 or less or 1/100 or less of the rotational speed in the processing.

Note that, the rotational speed for processing is for example set by the operator of the processing machine 1. From another viewpoint, the rotational speed for processing is prescribed by the NC program. Accordingly, when focusing on the processing machine 1 at the distribution stage, the relative relationship between the rotational speed for processing and the rotational speed for acquisition of the reference position need not be grasped as a requirement of the configuration of the processing machine 1. However, when it comes to the rotational speed for the processing, if a lower limit value able to be set by the operator is set in the processing machine 1 or there is a lower limit value recommended by the manufacturer in the specifications etc., that lower limit value may be compared with the rotational speed for acquisition of the reference position and whether the relationship as described above stands may be judged. If the rotational speed for processing prescribed by the NC program is referred to and the rotational speed prescribed in the NC program is not constant, the lowest rotational speed may be compared with the rotational speed for acquisition of the reference position.

The rotational speed for acquisition of the reference position for example may be set by the manufacturer of the processing machine 1 or may be set by the operator of the processing machine 1. From another viewpoint, the information of the rotational speed for acquisition of the reference position may be stored in advance in the storage part 67 or may be input to the control part 5 by operation of a not shown operation part in the processing machine 1 or the like. Note that, if the rotational speed for acquisition of the reference position is set by the operator, when focusing on the processing machine 1 at the distribution stage, the rotational speed for acquisition of the reference position need not be grasped as a requirement of the configuration of the processing machine 1 in the same way as the rotational speed for processing.

The speed of movement of the spindle 37 in the operation for acquiring the reference position may be made a suitable one. Further, this speed of movement may be constant or may not be constant (speed change may be carried out). As the latter mode, for example, there can be mentioned a mode of deceleration at the time when it approaches the predicted position of the reference position. The predicted position may be input to the control part 5 by the NC program or by operation by the operator of a not shown operation part. Further, the speed of movement at the time when the tool 101 contacts the workpiece 103 for acquisition of the reference position may be slower, equal, or faster relative to the speed of movement at the time when the tool 101 contacts the workpiece 103 for the processing. The speed of movement may be set by the manufacturer of the processing machine 1 or may be set by the operator of the processing machine 1. From another viewpoint, information of the speed of movement may be stored in advance in the storage part 67 or may be input to the control part 5 by operation with respect to a not shown operation part in the processing machine 1 or the like.

The control part 5 may control the Z-axis electric motor 39 so as to make the spindle 37 move targeting a position at the further −Z side from the predicted position of the reference position. Further, the spindle 37 may stop in the Z-direction due to the force received from the workpiece 103. The control part 5 may control the Z-axis electric motor 39 so as to generate a suitable torque so that the force of the tool 101 pushing against the workpiece 103 to the −Z side does not become excessively large. Further, based on the detection value of a suitable sensor, the control part 5 may detect deceleration or stopping in the Z-direction of the spindle 37 and may stop the drive operation of the Z-axis electric motor 39 in accordance with the detection. As the above sensor, for example, there can be mentioned the Z-axis position sensor 69, a sensor which detects the electric power supplied to the Z-axis electric motor 39, and a sensor (for example rotation sensor 71) which detects cessation of rotation of the spindle 37.

The control part 5, as described above, operates to make the tool 101 rotate by air from the nozzle 7 while making the tool 101 approach to the workpiece 103. If, in that state, cessation of rotation is detected by the rotation sensor 71 (or other sensor), the detection value of the Z-axis position sensor 69 at that time is made to be stored in the storage part 67 as the reference position.

Note that, for convenience, it is described that cessation of rotation is detected by the rotation sensor 71. However, strictly speaking, for example, when the number of rotations (from another viewpoint, the rotation speed) detected by the rotation sensor 71 becomes lower than a predetermined threshold value, the control part 5 may judge cessation of rotation. The threshold value may be set by the manufacturer of the processing machine 1 or may be set by the operator of the processing machine 1. From another viewpoint, the information of the threshold value may be stored in advance in the storage part 67 or may be input to the control part 5 by operation with respect to a not shown operation part in the processing machine 1 or the like.

Note that, parts of the operations shown in FIG. 5A and FIG. 5B may be carried out by manpower or may be carried out by operation by the operator with respect to a not shown operation part in the processing machine 1. As the above parts, for example, there can be mentioned rotation of the spindle 37 and/or movement of the spindle 37 to the −Z direction.

In the explanation up to here, as the reference member which the tool 101 strikes when acquiring the reference position, the workpiece 103 was explained as an example. However, the reference member may be another member which is unable to move relative to the workpiece 103. For example, the reference member may be the table 25 or chuck 27 or may be a dedicated member for acquiring the reference position which is detachably fixed to the table 25 or chuck 27. However, the above dedicated member may be grasped as a part of the table 25 or chuck 27 as well. In the explanation concerning acquisition of the reference position in the present disclosure, the term of the “workpiece 103” may be replaced by another term of the reference member described above unless contradictions arise.

### Summary of Embodiment

As explained above, the processing machine 1 has the spindle 37, holding part (table 25), drive part (Z-axis electric motor 39), position sensor (Z-axis position sensor 69), rotation sensor 71, and control part 5. The spindle 37 holds one of the tool 101 and workpiece 103 (tool 101 in the example shown). The holding part (table 25) holds the other of the tool 101 and workpiece 103 (workpiece 103 in the example shown). The Z-axis electric motor 39 makes the movable part (spindle 37), which is one of the spindle 37 and the table 25, move in a predetermined first direction (Z-direction). The Z-axis position sensor 69 detects the position of the spindle 37 in the Z-direction. The rotation sensor 71 detects the rotation of the spindle 37. At the time of processing of the workpiece 103 by the tool 101 in a state where the spindle 37 is rotating, the control part 5 controls the Z-axis electric motor 39 based on the detection value of the Z-axis position sensor 69 so as to the spindle 37 move in the Z-direction to the relative position set with respect to the predetermined reference position. Further, when the workpiece 103 or the member (for example table 25) which is unable to move relative to the workpiece 103 is referred to as the “reference member”, the control part 5 acquires, as the above reference position, the position detected by the Z-axis position sensor 69 at the time of detection of cessation of rotation of the spindle 37 by the rotation sensor 71 in a situation where the spindle 37 moves in the Z-direction in a state where the spindle 37 is rotating, and the tool 101 and the reference member contact in the Z-direction.

Further, from another viewpoint, the manufacturing method of the processed object according to the present embodiment uses the processing machine 1 as described above to obtain the processed object (for example workpiece 103 after cutting) by processing the workpiece 103 by the tool 101.

Accordingly, for example, as already explained, the tool 101 and the reference member (here, workpiece 103) which contacts the tool 101 need not have conductivity. Further, it is not necessary to use a conductive pseudo tool in place of the tool 101.

The first direction (Z-direction) for acquiring the above reference position may be a direction which crosses (for example, is perpendicular to) the rotation axis of the spindle 37. From another viewpoint, as in the example shown, in the mode where the tool 101 is a rotating tool, the outer peripheral part of the rotating tool may contact the reference member (for example workpiece 103) when acquiring the reference position. Otherwise, unlike the example shown, in the mode where the tool 101 is a turning tool, the outer peripheral part of the reference member (for example workpiece 103) may abut against the tool 101 at the time of acquisition of the reference position.

In this case, for example, although according to the configuration of the rotating tool (tool 101) or the like, compared with the mode where the front end of the rotating tool contacts the workpiece 103 (this mode is also included in the art according to the present disclosure), it is easier to make the rotation of the rotating tool stop by contact of the rotating tool and the workpiece 103. As the reason for that, it can be mentioned that the distance from the rotation axis of the rotating tool to the contact position of the rotating tool and the workpiece 103 is apt to become longer and/or that it is easier to make the contact area by the outer peripheral part of the rotating tool and the workpiece 103 larger.

The spindle 37 which holds one of the tool 101 and the workpiece 103 may hold the tool 101. The holding part which holds the other of the tool 101 and the workpiece 103 may be the table (table 25 and/or chuck 27) which is positioned at further one side (−Z side) in the first direction (Z-direction) from the spindle 37 and holds the workpiece 103. The tool 101 may be a blade having a cutting edge 101a on its outer periphery. The reference position may be the position at which the cutting edge 101a abuts against the workpiece 103 or table (in more detail, the surface on the other side (+Z side) in the Z-direction in this).

In this case, for example, the distance (radius of the blade) from the rotation axis CL of the tool 101 up to the position at which the tool 101 contacts the workpiece 103 is relatively largely secured, therefore the rotation of the tool 101 is easy to be stopped. As a result, it is easy to apply the method of acquiring the reference position in the present embodiment. Further, the position at which the cutting edge 101a abuts is defined as the reference position, therefore, the cutting amount (depth of groove) from the workpiece 103 can be controlled with a high precision. The reference position is acquired again when the wear of the cutting edge 101a advances, so the precision of the cutting amount can be maintained.

The processing machine 1 may further have the fluid supply part 9. Here, the tool 101 or workpiece 103 (tool 101 in the example shown) which is held upon the spindle 37 will be referred to as the “rotation target”. At this time, the fluid supply part 9 may realize rotation of the spindle 37 in the operation for acquiring the reference position by making the fluid strike at least one of the outer surface of the rotation target and the outer surface of the spindle 37 which is exposed to the outside.

In this case, for example, the reference position can be acquired by making the spindle 37 rotate by a drive source different from the drive source (spindle motor 41) driving the spindle 37 for processing. Accordingly, for example, compared with the mode where the spindle 37 is made to rotate by the spindle motor 41 for acquiring the reference position (this mode may also be included in the art according to the present disclosure), the rotational speed when acquiring the reference position can be set without regard as to the performance of the spindle motor 41. In turn, for example, it is made easy to make the rotational speed when acquiring the reference position low.

The fluid supply part 9 may realize rotation of the spindle 37 in the operation for acquiring the reference position by making the fluid strike the outer surface of the rotation target (tool 101 or workpiece 103).

In this case, for example, compared with the mode where the fluid strikes only the outer surface of the spindle 37 (this mode may also be included in the art according to the present disclosure), use of the device for supplying the processing fluid to the tool 101 or workpiece 103 at the time of processing also as the device for acquiring the reference position is facilitated. From another viewpoint, in the mode where the device for supplying the processing fluid at the time of processing is utilized also at the time of acquisition of the reference position, the configuration of this device can be simplified. Note that, as the device utilized for acquisition of the reference position, the device for supplying the processing fluid was taken as an example. However, a device for supplying air for cleaning use or another device may be utilized as well.

The tool 101 may be a blade having a cutting edge 101a on its outer periphery. The fluid supply part 9 may realize the rotation of the spindle 37 in the operation for acquiring the reference position by making the fluid strike the cutting edge 101a in a tangential direction of the cutting edge 101a.

In this case, for example, the above effect of the device for supplying the processing fluid being easily utilized for acquisition of the reference position is exhibited. Further, the fluid is made to strike a position where the distance from the rotation axis of the tool 101 is relatively long, therefore it is easy to make the tool 101 rotate. As a result, for example, the load of the fluid supply part 9 when acquiring the reference position is easily lightened.

The fluid supply part 9 may have the nozzle 7, the processing fluid supply source 49 which supplies the processing fluid to the nozzle 7, the gas supply source (air supply source 51) which supplies a gas to the nozzle 7, and the valve (control valve 53) which selectively connects the processing fluid supply source 49 and the air supply source 51 to the nozzle 7. The fluid supply part 9 may realize rotation of the spindle 37 in the operation for acquiring the reference position by supplying the gas (air) from the air supply source 51 from the nozzle 7.

In this case, for example, compared with the mode where the processing fluid is supplied when acquiring the reference position (this mode may also be included in the art according to the present disclosure), consumption of the processing fluid can be reduced. Further, for example, in a mode where the processing fluid is not water, and air is used as the gas, reduction of cost in the acquisition of the reference position is easy. Further, for example, compared with the mode where a liquid is supplied to the tool 101 (this mode may also be included in the art according to the present disclosure), it is easy to make the force which is given to the tool 101 smaller.

The rotational speed of the spindle 37 immediately before contact of the tool 101 with the reference member (for example workpiece 103) in the operation for acquiring the reference position may be made lower than the rotational speed of the spindle 37 when processing the workpiece 103 by the tool 101.

In this case, for example, the likelihood of deterioration of the tool 101 and/or reference member when acquiring the reference position is reduced. Note that, as already explained, the rotational speed for processing is set by the operator, therefore the above feature need not be specified in the processing machine 1 at the distribution stage.

The rotational speed of the spindle 37 when processing the workpiece 103 may be made 2000 rpm or more. In the operation for acquiring the reference position, the rotational speed of the spindle 37 immediately before contact of the tool 101 with the reference member (for example workpiece 103) may be made 100 rpm or less. Further, from another viewpoint, the rotational speed of the spindle 37 immediately before contact of the tool 101 with the reference member in the operation for acquiring the reference position may be made 1/100 or less of the rotational speed of the spindle 37 when processing the workpiece 103.

In these cases, for example, the rotational speed in the operation for acquiring the reference position is sufficiently low when compared with the rotational speed for processing. Accordingly, the likelihood of deterioration of at least one of the tool 101 and the reference member due to the contact of the two in the operation for acquiring the reference position is reduced.

The spindle 37 may be supported by an air bearing (bearing 43 illustrated in FIG. 3).

In this case, for example, compared with other types of bearings, the friction force for making the spindle 37 stop is small, therefore the spindle 37 can be made to rotate by a relatively small moment. As a result, for example, in the operation for acquiring the reference position, the moment which is given to the spindle 37 from the outside and/or the inertial moment of the spindle 37 can be made smaller. In turn, the moment which is given by the tool 101 to the workpiece 103 at the time of contact of the tool 101 with the workpiece 103 can be made smaller. As a result, the likelihood of deterioration of the tool 101 and/or reference member due to acquisition of the reference position is reduced.

Note that, in the above embodiment, the table 25 is one example of the holding part which holds the other of the tool and the workpiece. The Z-direction is one example of the first direction. The spindle 37 is one example of the movable part. The Z-axis electric motor 39 is one example of the drive part. The Z-axis position sensor 69 is one example of the position sensor. Each of the workpiece 103, chuck 27, and table 25 is one example of the reference member. The air supply source 51 is one example of the gas supply source. The control valve 53 is one example of the valve. The air is one example of the gas and the fluid.

The art according to the present disclosure is not limited to the above embodiment and may be executed in various ways.

In the explanation of the embodiment, the reference position was made a position of the movable part (one of the spindle and the holding part) in the first direction (Z-direction) in an absolute coordinate system. However, the reference position may be a relative position of the movable part relative to the other member (other of the spindle and the holding part) in the first direction. In this case, the position sensor which detects the position of the movable part in the first direction may be one sensor which detects the relative positions of the movable part and the other member or may be a combination of a sensor which detects the absolute position of the movable part and a sensor which detects the absolute position of the other member.

Further, for example, the fluid supply part which supplies the fluid to the rotation target (tool or workpiece) or the like in order to acquire the reference position and the fluid supply part which supplies the processing fluid may be made quite different devices as well.

### REFERENCE SIGNS LIST

1 . . . processing machine, 3 . . . machine body, 5 . . . control part, 7 . . . nozzle, 9 . . . fluid supply part, 25 . . . table (holding part), 37 . . . spindle, 39 . . . . Z-axis electric motor (drive part), 69 . . . . Z-axis position sensor (position sensor), 71 . . . rotation sensor, 101 . . . tool, and 103 . . . workpiece (reference member).

1. A processing machine comprising:
a spindle configured to hold one of a tool and a workpiece;
a holding part configured to hold the other of the tool and the workpiece;
a drive part configured to move a movable part embodying one of the spindle and the holding part in a predetermined first direction;
a position sensor configured to detect a position of the movable part in the first direction;
a rotation sensor configured to detect a rotation of the spindle; and
a control part configured to, at a time of processing of the workpiece by the tool in a state where the spindle is rotating, control the drive part based on a detection value of the position sensor so as to move the movable part to a relative position set with respect to a predetermined reference position in the first direction, wherein:
the workpiece or a member which is unable to move relative to the workpiece is referred to as a “reference member”,
the control part acquires as the reference position the position detected by the position sensor in response to cessation of rotation of the spindle being detected by the rotation sensor in a situation where the movable part moves in the first direction in a state where the spindle is rotating and the tool and the reference member contact in the first direction.

2. The processing machine according to claim 1, wherein the first direction is a direction crossing a rotation axis of the spindle.

3. The processing machine according to claim 2, wherein:
the spindle holds the tool;
the holding part comprises a table which is located at a further one side in the first direction from the spindle and holds the workpiece;
the tool comprises a blade having a cutting edge on its outer periphery; and
the reference position is the position at which the cutting edge contacts the workpiece or the table.

4. The processing machine according to claim 1, wherein:
the tool or the workpiece held upon the spindle is referred to as a “rotation target”;
the processing machine further comprises a fluid supply part configured to realize rotation of the spindle during the acquiring of the reference position by making fluid strike at least one of an outer surface of the rotation target and an outer surface exposed of the spindle to the outside.

5. The processing machine according to claim 4, wherein the fluid supply part is configured to realize rotation of the spindle during the acquiring of the reference position by making the fluid strike the outer surface of the rotation target.

6. The processing machine according to claim 5, wherein:
the tool comprises a blade having a cutting edge on its outer periphery; and
the fluid supply part is configured to realize rotation of the spindle during the acquiring of the reference position by making the fluid strike the cutting edge in a tangential direction of the cutting edge.

7. The processing machine according to claim 4, wherein:
the fluid supply part comprises:
a nozzle,
a processing fluid supply source configured to supply processing fluid to the nozzle,
a gas supply source configured to supply gas to the nozzle, and
a valve configured to selectively connect the processing fluid supply source and the gas supply source to the nozzle; and
the fluid supply part is configured to realize rotation of the spindle during the acquiring of the reference position by supplying the gas from the gas supply source from the nozzle as the fluid.

8. The processing machine according to claim 1, wherein a rotational speed of the spindle immediately before contact of the tool with the reference member during the acquiring of the reference position is lower than the rotational speed of the spindle at a time of processing of the workpiece by the tool.

9. The processing machine according to claim 8, wherein:
the rotational speed of the spindle when processing the workpiece is 2000 rpm or more; and
the rotational speed of the spindle immediately before contact of the tool with the reference member during the acquiring of the reference position is 100 rpm or less.

10. The processing machine according to claim 8, wherein the rotational speed of the spindle immediately before contact of the tool with the reference member during the acquiring of the reference position is 1/100 or less of the rotational speed of the spindle when processing the workpiece.

11. The processing machine according to claim 1, wherein the spindle is supported by an air bearing.

12. A method for manufacturing a processed object comprising using the processing machine of claim 1 to process the workpiece by the tool to obtain the processed object.

13. The processing machine according to claim 3, wherein:
the tool or the workpiece held upon the spindle is referred to as a “rotation target”;
the processing machine further comprises a fluid supply part configured to realize rotation of the spindle during the acquiring of the reference position by making fluid strike at least one of an outer surface of the rotation target and an outer surface exposed of the spindle to the outside.

14. The processing machine according to claim 13, wherein the fluid supply part is configured to realize rotation of the spindle during the acquiring of the reference position by making the fluid strike the outer surface of the rotation target.

15. The processing machine according to claim 14, wherein:
the tool comprises a blade having a cutting edge on its outer periphery; and
the fluid supply part is configured to realize rotation of the spindle during the acquiring of the reference position by making the fluid strike the cutting edge in a tangential direction of the cutting edge.

16. The processing machine according to claim 13, wherein:
the fluid supply part comprises:
a nozzle,
a processing fluid supply source configured to supply processing fluid to the nozzle,
a gas supply source configured to supply gas to the nozzle, and
a valve configured to selectively connect the processing fluid supply source and the gas supply source to the nozzle; and
the fluid supply part is configured to realize rotation of the spindle during the acquiring of the reference position by supplying the gas from the gas supply source from the nozzle as the fluid.

17. The processing machine according to claim 3, wherein a rotational speed of the spindle immediately before contact of the tool with the reference member during the acquiring of the reference position is lower than the rotational speed of the spindle at a time of processing of the workpiece by the tool.

18. The processing machine according to claim 4, wherein a rotational speed of the spindle immediately before contact of the tool with the reference member during the acquiring of the reference position is lower than the rotational speed of the spindle at a time of processing of the workpiece by the tool.

19. A method for manufacturing a processed object comprising using the processing machine of claim 3 to process the workpiece by the tool to obtain the processed object.

20. A method for manufacturing a processed object comprising using the processing machine of claim 4 to process the workpiece by the tool to obtain the processed object.
